(19) United States
(12) Patent Application Publication
(10) Pub. No.: US 2012/0205146 A1
(43) Pub. Date: Aug. 16, 2012

(54) HEAT-RESISTANT COPPER FOIL AND METHOD OF PRODUCING THE SAME, CIRCUIT BOARD, AND COPPER-CLAD LAMINATE AND METHOD OF PRODUCING THE SAME

(75) Inventors: Ryoichi Oguro, Tokyo (JP); Kazuhiro Hoshino, Tokyo (JP)

(73) Assignee: Furukawa Electric Co., Ltd., Tokyo (JP)

(21) Appl. No.: 13/390,403

(22) PCT Filed: Aug. 11, 2010
(86) PCT No.: PCT/JP10/63629

§ 371 Date: Mar. 27, 2012

(30) Foreign Application Priority Data
Aug. 14, 2009 (JP) 2009-188042

(51) Int. Cl. H05K 1/09; C25D 5/10; B32B 15/00; B32B 37/10; B32B 15/04

(52) U.S. Cl. 174/257; 156/151; 428/658; 428/621; 428/623; 205/177

(57) ABSTRACT

Disclosed is a copper foil which has excellent high frequency characteristics and heat resistance, while achieving high heat-resistant adhesion to a resin substrate at the same time. Specifically disclosed is a heat-resistant copper foil which has a configuration wherein a first roughened surface layer which has been treated by a first roughening treatment by copper metal, a second roughened surface layer which has been treated by a second roughening treatment by copper metal, and a third treated surface layer which has been treated by a third treatment process by zinc metal are sequentially provided on one surface of an untreated copper foil. Also specifically disclosed are: a circuit board which is obtained by laminating the heat-resistant copper foil on a flexible resin substrate or a rigid resin substrate; and a method for producing a copper-clad laminate wherein the heat-resistant copper foil and a heat-resistant resin substrate are thermally pressure-bonded and the roughened copper metal and the third treated surface layer of the zinc metal are alloyed.

### TECHNICAL FIELD

The present invention relates to a heat-resistant copper foil which is durable even under high temperature and high humidity conditions and further is excellent in the high frequency transmission characteristics indispensable for communication terminal functions, and to a method of producing a the heat-resistant copper foil.

Further, the present invention particularly relates to an electronic circuit board for control-use of vehicles such as hybrid electric vehicles and electric vehicles (hereinafter, referred to as HEVs and EVs) which ara durable under the high temperature and high humidity conditions, require long-term reliability, and further is excellent in the high frequency transmission characteristics indispensable for communication terminal functions.

Further, the present invention relates to a copper-clad laminate formed by laminating the heat-resistant copper foil and a heat-resistant resin substrate, and to a method of producing the same.

### BACKGROUND ART

As particularly represented by mobile phones among electronic devices, remarkable advances are being made on multiple functioning such as sending and reception of images and moving pictures of course and also GPS (global positioning system) functions, television reception, and various other multiple functions other than phone calls, in addition to reduction of size and thickness thereof. Such the technology is applied automobiles to dramatically improve convenience beyond electronic devices. In particular, in response to the demands for environmental protection in recent years, in motorization technology, reduction of emission of carbon dioxide is being tackled. Mass production and marketing of HEV's combining internal combustion engines and motors have already been commenced. Rising replacement demand is expected. Further, advances are also being made in solar power generation and increased capacity of rechargeable batteries. Plug-in EV's will also soon hit the market.

For example, luxury grade automobiles on the market mount inter-vehicle radar emitting high frequency waves to obtain a grasp of the distance from another object and radar detecting objects in the dark. Further, automobiles released for sale in recent years have antennas for receiving satellite broadcasts embedded in their roofs. Travel is being realized while making good use of the GPS function and enjoying pleasant media support.

For these radar, satellite broadcast, and other communication technologies, development of high frequency-compatible PCB (printed circuit boards) being able to cover the multiple gigahertz band to multiple tens of gigahertz band has become urgent business. For this high frequency-compatible control board, a combination of the technologies of the high frequency-compatible copper foil for forming a circuit and a resin substrate excellent in dielectric characteristic and heat resistance is indispensable. For example, PLT 1 discloses a copper foil for circuit board-use in which roughening particles are deposited on the surface of the copper foil to thereby improve the adhesive strength with a liquid crystal polymer film.

It is known that parts having electronic control functions which are mounted in not only automobiles having internal combustion engines, but also HEVs and EVs are used under severe conditions. In particular, in a computer box in which processing circuits for controlling the amount of injection of mixed gas in an internal combustion engine and processing circuits for controlling the rotation speed of the motor are housed, the wiring circuits generate heat the more frequent the processing process. In addition, the box itself is protected by an electromagnetic shield material, so the inside of the box becomes a high temperature and the control board inevitably also takes on heat.

In the past, as the method for eliminating heat of the computer box, a heat radiation system comprised of a stack of heat radiating aluminum plates is generally employed. However, due to the increase of number of times of processing along with a current multiple functions, there is a pressing need to greatly improve the heat radiation effect. Therefore, automobile manufacturers, electronic control component manufacturers, and consequently related PCB manufacturers are reviewing the designs of their circuit boards.

In order to improve the heat radiation effect, for example, the method like making the heat radiating aluminum plates thicker or larger or in some cases making holes to increase the surface area has been employed. However, even today, the number of functions is being increased and more circuits are being formed in limited board spaces. That is, the wave of reduction of thickness and reduction of size is spreading to the field of instruments including computer boxes as well, so improving the heat radiation efficiency is becoming increasingly difficult. Therefore, in order to improve the heat radiation efficiency, the design technique of making the board area of circuit boards smaller and making the thickness of those thinner is now being demanded.

In flexible boards, whose applications are expanding in printed circuit boards in recent years, the resin substrate is for example a typical industrial plastic film such as a PET (polyethylene terephthalate) film, PI (polyimide) film, and PC (polycarbonate) film. The method of bonding this to the copper foil of the circuit material through a binder is used. This method uses a binder for bonding, so does not need a copper foil having roughening particles. Therefore, a rolled copper foil rich in glossiness is mainly used at that method. However, while these materials can be used as members of mobile phones, mobile electronic terminals, and recording media of digital devices where the conditions of the applications used for are limited to the range of daily life, they cannot be employed for maintenance of adhesion under heat resistance conditions or for circuits to which a current from a low level to 40 to 50 A (amperes) is supplied from the viewpoint of long-term quality reliability.

Circuit boards for control of automobiles must be able to be properly operated under temperature change conditions exceeding the range of practical use. In order to design a narrow board area with a thin thickness while satisfying such a demand, a resin material which does not cause warping or cracking in a circuit board even under the conditions of temperature changes exceeding the range of practical use and a circuit metal material which follows that resin material in linear expansion coefficient value are demanded.

### CITATION LIST

### Patent Literature

PLT 1: Japanese Patent Publication (A) No. 2005-219379

### SUMMARY OF INVENTION

### Technical Problem

A copper foil having high frequency characteristics and other added value is required to be provided with the etchability which is necessary for forming a circuit, heat resistance and adhesion at the time of hot press lamination with a resin substrate excellent in heat resistance, and high transmission characteristics together with a resin base material. However, it has been considered that achievement of both an improvement of the adhesive strength and excellent transmission characteristics is physically extremely difficult.

The adhesion of copper foil with a resin substrate greatly depends on a physical anchoring effect into the resin substrate by surface asperity provided on the surface of the copper foil. For this reason, one surface of the copper foil is roughened by copper particles having sizes (shapes) rich in anchoring property. According to need, that treated surface is plated for improving the heat resistance or treated by a coupling agent having a chemical binder effect.

On the other hand, a high frequency current mainly flows through the surface layer. Therefore, in order to improve the high frequency transmission characteristics, it has been considered that the surface of the copper foil of the circuit material, has to have a smoothness of an extent corresponding to a mirror surface.

Due to the background on the art explained above, the side of the electrolytic copper foil bonded with the resin has been electroplating to impart adhesion so as to make the copper roughening particles lower in roughness, the heat-resistant adhesion has been maintained by plating a heavy metal other than copper, and the shortage of the adhesion caused by the anchoring effect has been compensated for by combined usage of a silane coupling agent to thereby clear the quality specifications. By such a technique, however, an electrolytic copper foil which has etching workability, high heat-resistant adhesion, and excellent transmission characteristics without migration defects cannot be provided. Appearance of an electrolytic copper foil as a circuit material satisfying these requests has been demanded.

### Solution to Problem

The present inventors engaged in intensive studies in order to satisfy the contradictory characteristics of smoothness (high frequency characteristics) and anchoring effect (adhesion with the resin substrate) and as a result first roughened the copper, treated the roughened surface with further finer fine roughening particles (copper bumps), plated the surface treated with the finer roughening particles with metal zinc to provide a zinc plated surface, and alloyed the roughening particles (metal copper) and the metal zinc by heat at the time of the lamination with the resin substrate to thereby form brass. The outermost surface now made brass enables the heat-resistant adhesion with the resin substrate to be sufficiently maintained without impairing the transmission characteristics. The inventors thereby reached the present invention.

The heat-resistant copper foil of the present invention is provided with the following surfaces in the following order: a first roughened surface treated by a first roughening treatment with metal copper on one surface of an untreated copper foil, a second roughened surface treated by a second roughening treatment with metal copper thereon, and a third treated surface treated by a third treatment with metal zinc.

The heat-resistant copper foil of the present invention is alternatively provided the following surfaces in the following order: a first roughened surface treated by a first roughening treatment with metal copper on one surface of an untreated copper foil, a second roughened surface treated by a second roughening treatment with metal copper thereon, a third treated surface treated by a third treatment with metal zinc thereon, and a chromate anti-corrosion layer treated by chromate.

The heat-resistant copper foil of the present invention is alternatively provided the following surfaces in the following order: a first roughened surface treated by a first roughening treatment with metal copper on one surface of an untreated copper foil, a second roughened surface treated by a second roughening treatment with metal copper thereon, a third treated surface treated by a third treatment with metal zinc thereon, a chromate anti-corrosion layer treated by chromate thereon, and a thin film layer treated by a silane coupling agent.

The method of producing a heat-resistant copper foil of the present invention includes a step of forming an untreated copper foil, a step of forming a first roughened treated surface with metal copper on one surface of the untreated copper foil, a step of forming a second roughened treated surface with metal copper on the first roughened treated surface, and a step of forming a third treated surface treated by metal zinc treatment on the second roughened treated surface.

The method of producing a heat-resistant copper foil of the present invention alternatively includes a step of forming an untreated copper foil of an electrolytic copper foil with a roughness of a foundation of a matte surface being a range of 1.5 to 3.5 μm, as an Rz value defined by JIS-B-0601, a step of forming a first roughened treated surface formed by copper roughening particles on the matte surface of the untreated copper foil, a step of forming a second roughened treated surface formed by copper roughening particles, to make a surface roughness of that surface within a range of 2.0 to 4.0 μm, as an Rz value defined by JIS-B-0601 on the first roughened treated surface, and a step of forming a third treated surface treated by metal zinc treatment on the second roughened treated surface.

The circuit board of the present invention is a circuit board formed by laminating the heat-resistant copper foil on a flexible resin substrate or a rigid resin substrate.

The method of producing a copper-clad laminate of the present invention includes a step of forming a heat-resistant copper foil by the following steps, forming an untreated copper foil, forming a first roughened treated surface with metal copper on one surface of the untreated copper foil, forming a second roughened treated surface with metal copper on the first roughened treated surface, and forming a third treated surface treated by metal zinc treatment on the second roughened treated surface, and including a step of hot press bonding the heat-resistant copper foil and a resin substrate having heat resistance and alloying the metal copper of the second roughened surface or the first roughened surface and the second roughened surface with the metal zinc of the third treated surface.

The method of producing a copper-clad laminate of the present invention alternatively includes a step of forming a heat-resistant copper foil by the following steps, forming an untreated copper foil, forming a first roughened treated surface with metal copper on one surface of the untreated copper foil, forming a second roughened treated surface with metal copper on the first roughened treated surface, forming a third treated surface treated by metal zinc treatment on the second roughened treated surface, and forming a chromate anti-corrosion layer treated by chromate on the third treated surface comprised of metal zinc, and including a step of hot press bonding the heat-resistant copper foil and a resin substrate having heat resistance and alloying the metal copper of the second roughened surface or the first roughened surface and the second roughened surface with the metal zinc of the third treated surface.

The method of producing a copper-clad laminate of the present invention alternatively includes a step of forming a heat-resistant copper foil by the following steps, forming an untreated copper foil, forming a first roughened treated surface with metal copper on one surface of the untreated copper foil, forming a second roughened treated surface with metal copper on the first roughened treated surface, forming a third treated surface treated by metal zinc treatment on the second roughened treated surface, forming a chromate anti-corrosion layer treated by chromate on the third treated surface formed by metal zinc, and forming a thin film layer formed by a silane coupling agent on the chromate anti-corrosion layer, and including a step of hot press bonding the heat-resistant copper foil and a resin substrate having heat resistance and alloying the metal copper of the second roughened surface or the first roughened surface and the second roughened surface with the metal zinc of the third treated surface.

The copper-clad laminate of the present invention is a copper-clad laminate produced by the method of producing the copper-clad laminate described above.

### Advantageous Effects of Invention

The heat-resistant copper foil of the present invention is excellent in adhesive strength with resins for which it is difficult to obtain adhesive strength such as Teflon® resin or glass epoxy-based resins having a large filler content (for example, conductor layer peel strength as prescribed in the standard JPCA-BU01-1998 of Japan Electronics Packaging and Circuits Association), is provided with both suitable elasticity/plasticity and heat resistance, is excellent in high frequency characteristics such as transmission loss, and has excellent effects as copper foil for forming a control circuit from which heat resistance is demanded including also automotive applications.

The heat-resistant copper foil of the present invention is excellent as a circuit material which is excellent in etching workability, high heat-resistant adhesion, and transmission characteristics without migration defects and can provide a circuit board from which the heat resistance is demanded, for example, which is suitable for a control circuit board for automotive use.

According to the method of producing the heat-resistant copper foil of the present invention, it is possible to produce a copper foil which is excellent in adhesive strength with resins for which it is difficult to obtain adhesive strength such as Teflon® resin or glass epoxy-based resins having a large filler content (for example, conductor layer peel strength as prescribed in the standard JPCA-BU01-1998 of the Japan Electronics Packaging and Circuits Association), is provided with both suitable elasticity/plasticity and heat resistance, is excellent in high frequency characteristics such as transmission characteristics, and is able to form a control circuit from which heat resistance is demanded including also automotive applications.

According to the method of producing the copper-clad laminate of the present invention, it is possible to provide a copper-clad laminate which is closely adhered with resins for which it is difficult to obtain adhesive strength such as Teflon® resin or glass epoxy-based resins having a large filler content, is excellent in high frequency characteristics such as transmission characteristics, and is able to form a control circuit from which heat resistance is demanded including also automotive applications.

### BRIEF DESCRIPTION OF DRAWINGS

FIG. 1 is a process diagram showing an example of the production processes of the present invention

### DESCRIPTION OF EMBODIMENTS

Hereinafter, a heat-resistant copper foil of the present invention which is excellent in high frequency transmission characteristics will be explained in detail.

In the high heat-resistant and high frequency-compatible copper foil of the present invention, one surface of the copper foil is treated by first roughening treatment by copper particles having a high anchoring effect under electrolytic burnt plating conditions in order to impart adhesion with a resin substrate. Next, copper particles made of fine copper roughening particles are deposited on the first roughened surface by electroplating as second roughening treatment. Next, in order to properly maintain the first and second roughened surfaces, the roughened surfaces are electroplated with metal zinc. For the formation of the zinc plating surface, in order to improve the chemical resistance, preferably a suitable vanadium metal, antimony metal, or trivalent chromium is added.

As the electrolytic copper foil, preferably copper foil with a foundation of the matte surface having an Rz value prescribed in JIS-B-0601 within a range of 1.5 to 3.5 μm is used.

The copper foil is preferably electrolytic copper foil comprised of columnar crystal grains. “Comprised of columnar crystal grains” means a state of a frost-like columnar structure in which crystal grains of the electrolytic copper foil grow in the thickness direction. The surface of the matte side has surface asperity shapes. In the present invention, at the tops of the asperity, first roughening particles comprised of copper particles are deposited. By depositing the copper particles primarily on the tops of the asperity of the columnar crystal grains in this way, a good anchoring effect is imparted.

Further, for use at a high temperature, if considering elongation of the heat-resistant resin to be bonded with the copper foil, preferably electrolytic copper foil which has an elongation at ordinary temperature after electrolytic foil production of 3.5% or more, preferably 5% or more, even in the thinnest copper foil having a thickness of 0.012 mm is used.

On the individual surfaces of the first roughened nodule copper particles, second fine copper nodule particles are deposited. The fine grains of copper obtained by the second roughening treatment are particularly uniformly deposited on the surface portions of the first roughening particles. The roughness after the second fine copper roughening treatment is preferably controlled to a range of the Rz value prescribed in JIS-B-0601 of 2.5 to 4.5 μm.

In the present invention, the surface after treatment by the first and second copper roughening treatment is provided with metal zinc having a heat resistance effect by third treatment. The amount of deposition of zinc of the zinc surface is preferably controlled to 2.5 to 4.5 mg/dm² as metal zinc.

Note that the surface of the zinc is preferably provided with a chromate anti-corrosion layer. The amount of deposition of chromium of the anti-corrosion layer is preferably controlled to 0.005 to 0.020 mg/dm² as metal chromium.

The surface of the anti-corrosion layer is preferably provided with a thin film layer comprised of a silane coupling agent. The amount of deposition of the silane coupling agent is preferably controlled to 0.001 to 0.015 mg/dm² as silicon.

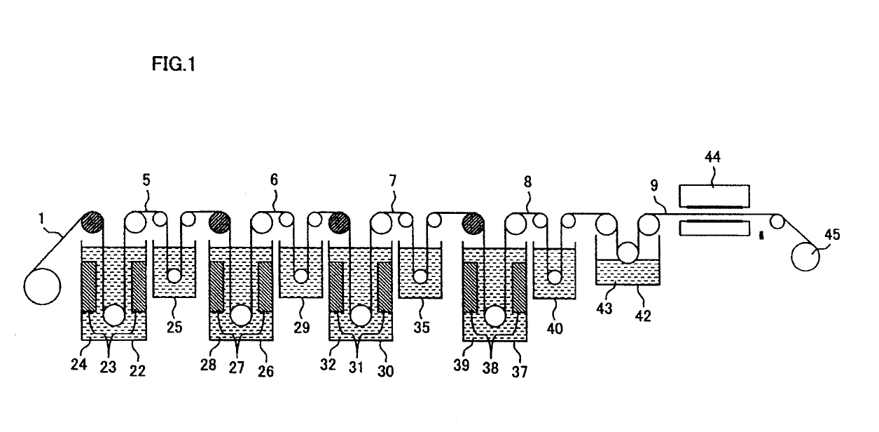

Next, an embodiment of the method of producing the heat-resistant copper foil of the present invention will be explained according to FIG. 1.

In FIG. 1, untreated copper foil (electrolytic copper foil, hereinafter, simply referred to as “copper foil”) 1 taken up around a reel is guided to a first treatment bath 22 for forming a first roughened copper particle surface. An iridium oxide anode 23 is arranged in the first treatment bath 22, a copper-sulfuric acid electrolytic solution 24 is filled in the bath, and a first roughened surface comprised of copper particles is formed. The copper foil 5 on which the first roughened surface was formed in the first treatment bath 22 is washed in a rinse bath 25, then guided to a second treatment bath 26.

In the second treatment bath 26, an iridium oxide anode 27 is arranged, a (copper-sulfuric acid) electrolytic solution 28 is filled in the same way as the first treatment bath, and second roughening treatment is performed. The copper foil 6 treated by the second roughening treatment is washed in a rinse bath 29, then guided to a third treatment bath 30. In the third treatment bath 30, an iridium oxide anode 31 is arranged, and a zinc electrolytic solution 32 is filled. The copper foil 7 treated by the zinc plating in the third treatment bath 30 is washed in a rinse bath 35, then guided to a fourth treatment bath 37. In the fourth treatment bath 37, an SUS anode 38 is arranged, a chromate electrolytic solution 39 is filled, and a chromate anti-corrosion layer is formed. The copper foil 8 on which the chromate anti-corrosion layer was formed in the fourth treatment bath 37 is washed in a rinse bath 40, then guided to a fifth treatment bath 42. A silane solution 43 is filled in the fifth treatment bath 42, and a silane coupling agent is coated on the surface of the copper foil 8. The copper foil 9 coated with the silane coupling agent in the fifth treatment bath 42 passes through a drying process 44 and is taken up around a winding roll 45.

It is also possible to use rolled copper foil as the untreated copper foil 1. However, in order to improve the adhesion with a resin substrate concerned, copper foil having as much surface asperity and undulation over the roughened surface as possible is advantageous. Therefore, it is prefer to use an electrolytic copper foil having a crystal structure comprised of columnar crystal grains produced according to general purpose electrolytic foil production conditions, having a thickness of 0.012 mm or more, having a shape roughness after electrolytic foil production on the matte surface side (electrodeposition solution surface side) of the Rz value prescribed in JIS-B-0601 in a range of 1.5 to 3.5 μm, and having an elongation at ordinary temperature of 3.5% or more.

The copper foil of the present invention is used in specifications suitable for high frequency circuit boards, particularly control circuit boards for automobiles, therefore heat resistance and transmission characteristics are valued. For this reason, as the resin substrate to be laminated with the copper foil, one which does not expand and contract during the heat history, for example, a Teflon®-based resin material, is used.

In this way, since a resin material with little elongation is laminated with and the board does not warp, bend, or otherwise deform after formation of the circuits, copper foil with a particularly good elongation is not necessary. The elongation may be 3.5% or more, preferably 5% or more. Further, a high elongation does not cause a problem, therefore it is not necessary to provide an upper limit value.

The first roughening treatment for treatment of the matte surface of the copper foil 1 is performed in the first treatment bath 22 by a cathode electroplating method using a copper sulfate bath to which metal molybdenum is added.

The first roughening treatment forms nodule-shaped roughening particles of copper on the surface of the copper foil. As that method, by setting the copper sulfate to 20 to 30 g/L as copper, the concentration of the sulfuric acid to 90 to 110 g/L as H₂SO₄, the sodium molybdate to 0.15 to 0.35 g/L as Mo, the chlorine to 0.005 to 0.010 g/L by chlorine ion conversion, the bath temperature to 18.5 to 28.5° C., and the electrolytic burnt plating current density to 28 to 35 A/dm², and by suitable flow rate and interelectrode distance suitable copper nodule roughening particles can be formed on the surface of the copper foil. Note that, preferably, smooth electroplating is performed under conditions setting the current density to about 15 to 20 A/dm² according to need in the same bath so that the copper nodule roughening particles will not drop out.

Next, in order to improve the adhesion with the resin substrate, fine grains of second roughening copper particles are formed on the first copper roughening particles formed in the previous step. This treatment by the fine copper roughened particle is basically based on the bath composition of the first treatment bath, and the characterizing feature resides in making the concentration of the copper sulfate as copper a lean 4 to 6 g/L. By setting the bath temperature at 18.5 to 28.5° C., setting the electrolytic burnt plating current density to 5 to 10 A/dm², and setting a suitable flow rate and interelectrode distance, a suitable copper surface roughened by fine copper particles can be formed. The second roughened copper particles applied in the second roughening treatment are fine grains. The size of the individual nodules of the metal copper applied in the second roughening treatment is preferably controlled to about ¼ to ¾ of the size of the individual copper bumps applied in the first roughening. The fine grains of the second roughening make the surfaces have improving the adhesion with the resin substrate and simultaneously not impairing the high frequency transmission characteristics. From the viewpoint of practical use, the size of the second roughened copper particles is preferably controlled to about ¼ to ¾ of the size of the individual copper nodules of the first roughening.

The adhesion with the resin substrate can be secured by the steps up to this point. However, the adhesion with the resin substrate at the time of a high temperature (assumed temperature is 288° C. which is the maximum temperature when the condition of a lead-free solder reflow process is performed) is poor, therefore the second roughened surface is treated to improve the heat resistance. In the present invention, it is possible to obtain an anchoring effect without impairing the formation of copper roughened particle shapes formed in the previous step and to achieve both adhesion with the resin substrate and the heat resistance characteristic at the time of a high temperature by forming a suitable thickness of zinc by smooth electroplating.

The bath composition of dissolved zinc for electroplating the metal zinc is not particularly limited so far as it is a soluble zinc compound. However, preferably zinc sulfate is used. The bath composition is preferably obtained by dissolving 3.5 to 6.0 g/l of zinc by using zinc sulfate, 18 to 40 g/l of sodium hydroxide, and, in order to impart chemical resistance, as additives, 0.1 to 0.5 g/l of vanadium from a vanadium compound or 0.3 to 1.0 g/l of antimony from an antimony compound.

The amount of deposition of the smooth plating of zinc is preferably controlled to 2.5 to 4.5 mg/dm² as metal zinc. If the amount of deposition is within such a range, when laminating the copper foil and the resin substrate to prepare a single-sided copper-clad laminate, the zinc is sufficiently thermally diffused together with the roughened copper particles of the lower layer under the hot pressing condition of about 160 to 240° C., and they form an alloy of copper and zinc, that is, brass. The surface of this brass will not cause deformation of the roughened shape.

The surface layer which becomes brass will not impair the high frequency transmission characteristic. For example, in copper foil of a thickness of 0.012 mm where the effect on the transmission characteristic is most marked, the conductivity which is measured according to the measurement method of electrical resistance prescribed in JIS-C-3001 is 98.7% when it is measured in a surface treatment-free (untreated copper foil) state after electrolytic foil production. In contrast to this, the conductivity of copper foil formed into brass by plating the above amount of zinc and further heating to 180° C. to cause the zinc to diffuse is 98.4%. There is almost no effect.

Next, the zinc-treated surface, according to need, is coated with a chromate corrosion inhibitor by dipping or, according to need, is treated by cathode electrolytic treatment (fourth treatment bath 38) to provide an anti-corrosion layer and thereby improve the corrosion-proofing ability. In this way, the corrosion-proofing is performed after the zinc plating, and in this case, the heat resistance is valued, so chromate corrosion-proofing by a chromic acid solution is preferable because of excellent cost performance. In recent years, even among organic-based corrosion inhibitors such as benzotriazole, derivative compounds which are excellent in heat resistance are on the market. However, they are still poor in proven performance in the point of long-term reliability, therefore in the present invention, the chromate corrosion-proofing is used.

The thickness of the coating film in the case of chromate treatment is preferably within a range of 0.005 to 0.025 mg/dm² as the amount of metal chromium. Within this range of deposition amount, the surface is not discolored to the color of copper oxide until 24 hours have passed under the salt spray test (concentration of salt water: 5% of NaCl, temperature: 35° C.) conditions prescribed in JIS-Z-2371.

Further, preferably, the chromate-treated surface, according to need, is suitably coated with a silane coupling agent to thereby improve the adhesion with a Teflon® resin substrate or filler-containing resin substrate. The silane coupling agent is suitably selected according to the resin substrate concerned. In particular, an amino-based, vinyl-based, or methacryloxy-based coupling agent excellent for a high frequency-compatible board is preferably selected. Further, in the present invention, the type is not particularly limited, but, at least, in order to chemically improve the adhesion with the resin substrate, preferably the amount of deposition of the silane coupling agent on the matte surface side is within a range of 0.001 to 0.015 mg/dm² as silicon.

### Example 1

Using untreated electrolytic copper foil having a thickness of 0.035 mm produced under known electrolytic foil production conditions, having a shape roughness on its matte surface side (electrodeposition solution side) of an Rz value prescribed in JIS-B-0601 of 1.8 μm, and having an elongation at ordinary temperature of 6.2% (electrolytic copper foil produced by Furukawa Electric), the matte surface side was treated on its surface under the following conditions.

Bath Composition for Formation of First Copper Roughening Particle and Treatment Conditions

| | |
|---|---|
| Use of copper sulfate to give, as metal copper | 23.5 g/L |
| As sulfuric acid | 100 g/L |
| Use of sodium molybdate to give, as molybdenum | 0.25 g/L |
| Hydrochloric acid as chlorine ions | 0.002 g/L |
| Ferric sulfate as metal iron | 0.20 g/L |
| Chromium sulfate as trivalent chromium | 0.20 g/L |
| Bath temperature: | 25.5° C. |
| Electroplating current density at bath inlet side: | 28.5 A/dm² |
| Electroplating current density at bath outlet side: | 12.5 A/dm² |

Second Fine Copper Roughening Particle Treatment Conditions

| | |
|---|---|
| Use of copper sulfate to give, as metal copper | 5.5 g/L |
| As sulfuric acid | 50 g/L |
| Use of sodium molybdate to give, as molybdenum | 0.25 g/L |
| Hydrochloric acid as chlorine ions | 0.002 g/L |
| Ferric sulfate as metal iron | 0.20 g/L |
| Chromium sulfate as trivalent chromium | 0.20 g/L |
| Bath temperature: | 18.5° C. |
| Electroplating current density at bath inlet side: | 12.5 A/dm² |

Metal Zinc Plating Conditions

| | |
|---|---|
| Zinc sulfate as metal zinc | 4.0 g/L |
| As sodium hydroxide | 25.5 g/L |
| pH: | 12.5 to 13.5 |
| Bath temperature: | 18.65° C. |
| Electroplating current density: | 5.5 A/dm² |

For the corrosion-proofing, the foil was dipped into a bath containing 3 g/L of CrO₃ and then dried to form a chromate layer. After that, as the silane coupling treatment, a methacryl-based silane coupling agent (Sila-Ace S-710 made by Chisso Corporation) set to 0.5 wt % and a pH of 3.5 was coated on only the matte surface side of the copper foil to form a thin membrane.

The surface roughness of the surface treated surface (matte surface side) of the obtained surface-treated copper foil, obtained by measuring the Rz value prescribed in JIS-B-0601, is described in Table 1. Further, the treated copper foil was cut into 250 mm squares, superimposed over a commercially available polyphenylene ether (PPE) resin substrate (MEGTRON-6 prepreg made by Panasonic Electric Works Corporation used) with its treated surface (matte surface side), and hot pressed for lamination to thereby prepare a single-sided copper-clad laminate for measurement of adhesion. The hot pressing conditions were made 160° C. for 60 minutes.

For measurement and evaluation of the heat resistance, the treated surface (matte surface side) was superimposed over a commercially available glass epoxy resin substrate (LX67N prepreg made by Hitachi Chemical Co., Ltd. used) and hot pressed for lamination to prepare a single-sided copper-clad laminate. This was subjected to a moisture absorption accelerated test, then dipped for 30 seconds in a solder bath kept at 288° C. to thereby obtain a heat resistance evaluation test piece for evaluating the presence of any blisters.

In the evaluation of the high frequency characteristics, superiority was relatively evaluated according to the results of measurement of the transmission loss. The treated surface (matte surface side) was superimposed over a commercially available liquid crystal polymer-based resin substrate (ULTRALAM3000 made by Rogers Corporation used), then laminated by a single-sheet hot press in the present evaluation in place of lamination by continuous lamination to prepare a single-sided copper-clad laminate and thereby obtain a test piece for measuring the transmission loss.

The adhesion with the resin base material was measured according to the measurement method prescribed in JIS-C-6481 and was described as the adhesive strength in Table 1.

Further, as the judgment of the heat resistance, the single-sided copper-clad laminate was cut into 50 mm sized square pieces to prepare five test pieces under each conditions. These were pretreated under PCT (pressure cooker test) conditions (relative humidity of 100%, 2 atm, 121° C., 120 minutes), then the test pieces were dipped in a solder bath set at 288° C. for 30 seconds. The presence of swelling between the copper foils and substrates was described in Table 1 evaluating the case of no blisters at all generated in all of the test pieces as “very good”, the case of one minor blister of less than 5 mm diameter generated at one piece of the test pieces as “good”, a case of two to three blisters of less than 5 mm diameter generated as “fair”, and a case of blisters of 5 mm diameter or more generated regardless of the number of those as “poor”.

In the evaluation of the transmission characteristics, the known strip-line resonator technique, suitable for measurement in the 1 to 25 GHz zone (method of measuring S21 parameter in state where microstrip structure: dielectric thickness of 50 μm, conductor length of 1.0 m, conductor thickness of 12 μm, conductor circuit width of 120 μm, characteristic impedance of 50Ω, and no coverlay film [for example, this is because the transmission loss becomes large and the judgment of difference becomes incorrect if a coverlay having poor dielectric characteristics was used]) was used for continuous measurement from 1 to 15 GHz. Among these measurement values, the transmission losses (dB/100 mm) corresponding to the frequencies of 5, 10, and 15 GHz were described in Table 1 as relative values when the transmission loss value of a GTS-MP-35 μm foil (loss value of Comparative Example 1) was assumed to be 100.

### Example 2

The untreated copper foil used in Example 1 was used, roughened and surface treated in the same way as in Example 1 to give a roughness of the obtained surface treated side of an Rz value of approximately 2.0 μm, and evaluated and measured in the same way as Example 1. The results are described in Table 1.

### Example 3

The untreated copper foil used in Example 1 was used, roughened and surface treated in the same way as in Example 1 to give a roughness of the obtained surface treated side of an Rz value of approximately 4.0 μm, and evaluated and measured in the same way as Example 1. The results are described in Table 1.

### Example 4

The untreated copper foil used in Example 1 was used, roughened and surface treated in the same way as in Example 1 to give a roughness of the obtained surface treated side of an Rz value of approximately 6.0 μm, and evaluated and measured in the same way as Example 1. The results are described in Table 1.

### Example 5

The untreated copper foil used in Example 1 was used, roughened and surface treated in the same way as in Example 1 to give a roughness of the obtained surface treated side of an Rz value of approximately 8.0 μm, and evaluated and measured in the same way as Example 1. The results are described in Table 1.

### Comparative Example 1

The matte surface side of the untreated copper foil used in Example 1 was treated by first and second copper roughening treatment the same as in Example 1, then plated with copper by smooth capsule plating, then the surface treated layer was electroplated using the following nickel bath and zinc bath, performed the corrosion-proofing treatment and the silane coupling agent treatment in the same way as in Example 1, and evaluated and measured in the same way as in Example 1. The results are described in Table 1 jointly.

Smooth Capsule Plating Treatment Conditions of Copper

| | |
|---|---|
| Use of copper sulfate to give, as metal copper | 52.5 g/L |
| As sulfuric acid | 100 g/L |
| Hydrochloric acid as chlorine ions | 0.002 g/L |
| Bath temperature: | 45.5° C. |
| Electroplating current density: | 18.5 A/dm² |

Nickel Plating Conditions of GTS Treatment

| | |
|---|---|
| Use of nickel sulfate to give, as metal nickel | 5.0 g/L |
| As ammonium persulfate | 40.0 g/L |
| As boric acid | 28.5 g/L |
| pH: | 3.5 to 4.2 |
| Bath temperature: | 28.5° C. |

Zinc Plating Conditions of Known GTS Treatment

| | |
|---|---|
| Use of zinc sulfate to give, as metal zinc | 4.8 g/L |
| As sodium hydroxide | 35.0 g/L |
| pH: | 12.5 to 13.8 |
| Bath temperature: | 18.5° C. |
| Electroplating current density: | 0.8 A/dm² |

### Comparative Example 2

The untreated copper foil used in Example 1 was treated in the same way as Example 1, except for not performing the first roughening treatment, from the second fine roughening treatment on and was evaluated and measured in the same way as Example 1. The results are described in Table 1 jointly.

### Comparative Example 3

Using as the untreated copper foil a rolled copper foil having a thickness of 17.5 μm, a surface shape roughness of an Ra value prescribed in JIS-B-0601 of 0.1 μm (Rz value: 0.45 μm) and an elongation at ordinary temperature of 2.8% (rolled copper foil obtained by rolling by Nippon Foil Mfg. Co., Ltd.), one surface was treated by exactly the same conditions as Example 1 and evaluated and measured in the same way as Example 1. The results are described in Table 1 jointly.

TABLE 1

| | Roughness before | Roughness after | | | | | | |
|---|---|---|---|---|---|---|---|---|
| | treated surface | treated surface | | Zinc deposition | | | | |
| | side roughening | side roughening | Adhesive | amount of treated | Heat resistance | | | |
| | treatment, Rz value | treatment, Rz value | strength, | surface side, | of 30 sec/288° C. | Transmission loss, index | | |
| | [μm] | [μm] | [kg/cm] | [mg/dm²] | [n = 5] | 5 GHz | 10 GHz | 15 GHz |
| Ex. 1 | 1.80 | 3.80 | 0.85 | 3.50 | Very good | 44 | 47 | 50 |
| Ex. 2 | 1.80 | 2.05 | 0.73 | 3.85 | Fair | 33 | 38 | 47 |
| Ex. 3 | 1.80 | 3.95 | 0.88 | 3.35 | Very good | 45 | 52 | 56 |
| Ex. 4 | 1.80 | 5.80 | 1.25 | 3.15 | Very good | 65 | 77 | 82 |
| Ex. 5 | 1.80 | 7.85 | 1.48 | 3.05 | Very good | 85 | 88 | 90 |
| Comp. Ex. 1 | 1.80 | 6.85 | 1.32 | 0.28 | Good | 100 | 100 | 100 |
| Comp. Ex. 2 | 1.80 | 1.95 | 0.55 | 4.05 | Poor | 30 | 38 | 42 |
| Comp. Ex. 3 | 0.45 | 1.55 | 0.35 | 4.35 | Poor | 27 | 33 | 41 |

As apparent from Table 1, the copper foils of Examples 1 to 5 had the satisfactory adhesive strength with the resin substrate of 0.7 kg/cm or more thought to be necessary.

Further, Examples 1 to 5 had small satisfactory transmission losses. The cause of the reduction of the transmission characteristics is believed to have been the formation of the brass layer by alloying of the surface layer of the copper foil with zinc under the heat treatment conditions at the time of hot pressing for laminating the copper foil together with the resin substrate. On the other hand, in Comparative Example 1, which is the general purpose type copper foil, the adhesive strength and the heat resistance are satisfactory, but the practicality is poor regarding the transmission loss. The cause of the poor transmission loss compared with the examples is believed to have been the use of nickel and zinc for the surface treatment and therefore the surface layer of the copper foil not becoming a brass layer under the heat treatment conditions at the time of hot pressing for laminating the copper foil together with the resin substrate, so the surface remaining rough as it is.

The solder-dipped heat resistance after moisture absorption was “fair” in Example 2, because the surface roughness in Example 2 was small, however, there was no obstacle to practical use. The other examples were all satisfactory.

Comparative Example 2 and Comparative Example 3 did not satisfy either the adhesive strength or heat resistance. The transmission loss characteristic was a little superior to the examples due to the small effect of the roughness Rz, but the results were not practical regarding the evaluation of the adhesion with the resin substrate and heat resistance required.

As explained above, the heat-resistant copper foil excellent in the high frequency transmission characteristics of the present invention is excellent in adhesive strength with resins for which it is difficult to obtain adhesive strength such as Teflon® resin or glass epoxy-based resins having a large filler content (JPCA), is provided with both suitable elasticity/plasticity and heat resistance, is excellent in high frequency characteristics such as transmission characteristics, can sufficiently maintain the adhesion with the resin substrate as a control circuit frequently using transmission for high frequency applications of HEV's and EV's, has suitable heat resistance and humidity resistance even under severe natural climate conditions and even at the time of heat generation of the control circuit itself, and further enables the characteristics of the high frequency-compatible substrate to be suitably exhibited without the roughening shape and surface treated metal impairing the transmission characteristics (transmission loss is small and transmission property is excellent).

The heat-resistant copper foil excellent in the high frequency transmission characteristics of the present invention does not use a surface treated material which would obstruct etchability and accordingly is free from problems in etchability, has a high heat-resistant adhesion, and is excellent as a circuit material free of migration defect and excellent in transmission characteristics. It is therefore possible to provide a circuit board suitable as for example a control circuit board for an automobile which is required to have heat resistance.

According to the method of producing a heat-resistant copper foil excellent in high frequency transmission characteristics of the present invention, it is possible to easily produce, without requiring any special apparatus, a copper foil which is excellent in adhesive strength with resins for which it is difficult to obtain adhesive strength such as Teflon® resin or glass epoxy-based resins having a large filler content (JPCA), is provided with both suitable elasticity/plasticity and heat resistance, is excellent in high frequency characteristics such as transmission characteristics, and forms a control circuit which is required to have heat resistance including also automotive applications.

According to the method of producing a copper-clad laminate of the present invention, it is possible to provide a copper-clad laminate which is closely adhered with resins for which it is difficult to obtain adhesive strength such as Teflon® resin or glass epoxy-based resins having a large filler content, is excellent in high frequency characteristics such as transmission characteristics, and exhibits advantageous effects as a copper-clad laminate for formation of a control circuit which frequently uses transmission for high frequency applications for HEVs and EVs and is required to have heat resistance.

Further, according to the method of producing the copper foil of the present invention, the first roughening and the second fine roughening can be continuously performed properly and cheaply. Therefore, even if the spread of EVs is promoted from the viewpoint of future environmental considerations, it is possible to sufficiently deal with both of supply side and characteristic side.

### INDUSTRIAL APPLICABILITY

The heat-resistant copper foil according to the present invention and the method of producing the same can be utilized for heat-resistant copper foil excellent in high frequency transmission characteristics, a method of producing that heat-resistant copper foil, a copper-clad laminate formed by laminating the heat-resistant copper foil and a heat-resistant resin substrate, and a method of producing the same.

### REFERENCE SIGNS LIST

1 untreated copper foil
22 first treatment bath (first copper roughening particle treatment and formation step)
26 second treatment bath (second copper fine roughening particle treatment and formation step)
30 third treatment bath (zinc plating step)
37 fourth treatment bath (corrosion-proofing step)
   42 fifth treatment bath (silane coupling)
   44 drying step

1. A heat-resistant copper foil, provided the following surfaces in the following order:
a first roughened surface treated by a first roughening treatment with metal copper on one surface of an untreated copper foil,
a second roughened surface treated by a second roughening treatment with metal copper thereon, and
a third treated surface treated by a third treatment with metal zinc.

2. A heat-resistant copper foil, provided the following surfaces in the following order:
a first roughened surface treated by a first roughening treatment with metal copper on one surface of an untreated copper foil,
a second roughened surface treated by a second roughening treatment with metal copper thereon,
a third treated surface treated by a third treatment with metal zinc thereon, and
a chromate anti-corrosion layer treated by chromate.

3. A heat-resistant copper foil, provided the following surfaces in the following order:
a first roughened surface treated by a first roughening treatment with metal copper on one surface of an untreated copper foil,
a second roughened surface treated by a second roughening treatment with metal copper thereon,
a third treated surface treated by a third treatment with metal zinc thereon,
a chromate anti-corrosion layer treated by chromate thereon, and
a thin film layer treated by a silane coupling agent.

4. A heat-resistant copper foil as set forth in any one of claims 1 to 3, wherein an amount of deposition of the metal zinc of the third treated surface is between 2.5 to 4.5 mg/dm².

5. A heat-resistant copper foil as set forth in any one of claims 1 to 3, wherein the untreated copper foil is an electrolytic copper foil, the one surface is a matte surface, and the roughness of the foundation of the matte surface is within a range of 1.5 to 3.5 μm, as an Rz value defined by JIS-B-0601.

6. A heat-resistant copper foil as set forth in claim 5, wherein the electrolytic copper foil has an elongation at normal temperature of 3.5% or more.

7. A heat-resistant copper foil as set forth in any one of claims 1 to 3, wherein the second roughened surface treated by the second roughening treatment has a roughness within a range of 2.0 to 4.0 μm, as the Rz value defined by JIS-B-0601.

8. A heat-resistant copper foil as set forth in claim 2 or 3, wherein the chromate anti-corrosion layer has an amount of chromium deposition of 0.005 to 0.025 mg/dm², as metal chromium.

9. A heat-resistant copper foil as set forth in claim 3, wherein the thin film layer treated by the silane coupling agent has an amount of deposition of the silane coupling agent of 0.001 to 0.015 mg/dm², as silicon.

10. A method of producing a heat-resistant copper foil including:
a step of forming an untreated copper foil,
a step of forming a first roughened treated surface with metal copper on one surface of the untreated copper foil,
a step of forming a second roughened treated surface with metal copper on the first roughened treated surface, and
a step of forming a third treated surface treated by metal zinc treatment on the second roughened treated surface.

11. A method of producing a heat-resistant copper foil including:
a step of forming an untreated copper foil of an electrolytic copper foil with a roughness of a foundation of a matte surface being a range of 1.5 to 3.5 μm, as an Rz value defined by JIS-B-0601,
a step of forming a first roughened treated surface formed by copper roughening particles on the matte surface of the untreated copper foil,
a step of forming a second roughened treated surface formed by copper roughening particles, to make a surface roughness of that surface within a range of 2.0 to 4.0 μm, as an Rz value defined by JIS-B-0601 on the first roughened treated surface, and
a step of forming a third treated surface treated by metal zinc treatment on the second roughened treated surface.

12. A method of producing a heat-resistant copper foil as set forth in claim 10 or 11,
wherein the untreated copper foil has an elongation at ordinary temperature of 3.5% or more.

13. A circuit board formed by laminating the heat-resistant copper foil, as set forth in any one of claims 1 to 9, on a flexible resin substrate or a rigid resin substrate.

14. A method of producing a copper-clad laminate:
including a step of forming a heat-resistant copper foil by the following steps,
forming an untreated copper foil,
forming a first roughened treated surface with metal copper on one surface of the untreated copper foil,
forming a second roughened treated surface with metal copper on the first roughened treated surface, and
forming a third treated surface treated by metal zinc treatment on the second roughened treated surface, and
including a step of hot press bonding the heat-resistant copper foil and a resin substrate having heat resistance and alloying the metal copper of the first roughened surface and the second roughened surface or the second roughened surface with the metal zinc of the third treated surface.

15. A method of producing a copper-clad laminate:
including a step of forming a heat-resistant copper foil by the following steps,
forming an untreated copper foil,
forming a first roughened treated surface with metal copper on one surface of the untreated copper foil,
forming a second roughened treated surface with metal copper on the first roughened treated surface,
forming a third treated surface treated by metal zinc treatment on the second roughened treated surface, and
forming a chromate anti-corrosion layer treated by chromate on the third treated surface comprised of metal zinc, and
including a step of hot press bonding the heat-resistant copper foil and a resin substrate having heat resistance and alloying the metal copper of the first roughened surface and the second roughened surface or the second roughened surface with the metal zinc of the third treated surface.

16. A method of producing a copper-clad laminate:
including a step of forming a heat-resistant copper foil by the following steps,
forming an untreated copper foil,
forming a first roughened treated surface with metal copper on one surface of the untreated copper foil,
forming a second roughened treated surface with metal copper on the first roughened treated surface,
forming a third treated surface treated by metal zinc treatment on the second roughened treated surface,
forming a chromate anti-corrosion layer treated by chromate on the third treated surface formed by metal zinc, and
forming a thin film layer formed by a silane coupling agent on the chromate anti-corrosion layer, and
including a step of hot press bonding the heat-resistant copper foil and a resin substrate having heat resistance and alloying the metal copper of the first roughened surface and the second roughened surface or the second roughened surface with the metal zinc of the third treated surface.

17. A copper-clad laminate produced by the method of producing as set forth in any one of claims 14 to 16.
